(19) United States
(12) Patent Application Publication
(10) Pub. No.: US 2008/0276860 A1
(43) Pub. Date: Nov. 13, 2008

(54) CROSS FLOW APPARATUS AND METHOD FOR HYDRIDE VAPOR PHASE DEPOSITION

(76) Inventors: BRIAN H. BURROWS, San Jose, CA (US); Jacob Grayson, Santa Clara, CA (US); Nyi O. Myo, Campbell, CA (US); Ronald Stevens, Santa Ramon, CA (US); Kenric T. Choi, Santa Clara, CA (US); Sumedh Acharya, Santa Clara, CA (US); Sandeep Nijhawan, Los Altos, CA (US); Lori D. Washington, Union City, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/747,133

(22) Filed: May 10, 2007

(51) Int. Cl. C30B 23/02; C23C 16/34

(52) U.S. Cl. 117/102; 117/88; 117/98; 118/726

(57) ABSTRACT

A method and apparatus for hydride vapor phase epitaxial (HVPE) deposition is disclosed. In the HVPE process, a hydride gas flows over a metal source to react with the metal source, which then reacts at the surface of a substrate to deposit a metal nitride layer. The metal source comprises gallium, aluminum, and/or indium. The hydride gas is evenly provided over the metal source to increase efficiency of hydride-metal source reaction. An exhaust positioned diametrically across the chamber from the metal source creates a cross flow of the hydride-metal source product and nitrogen precursor across the chamber tangential to the substrate. A purge gas flowing perpendicular to the cross flow directs the hydride-metal source product and nitrogen precursor to remain as close to the substrate as possible.

### BACKGROUND OF THE INVENTION

1. Field of the Invention

Embodiments of the present invention generally relate to an apparatus for hydride vapor phase epitaxial (HVPE) deposition. Additional embodiments of the present invention generally relate to a HVPE deposition method.

2. Description of the Related Art

Group-III nitride semiconductors are finding greater importance in the development and fabrication of short wavelength light emitting diodes (LEDs), laser diodes (LDs), and electronic devices including high power, high frequency, and high temperature transistors and integrated circuits. One method that has been used to deposit Group-III nitrides is HVPE. In HVPE, a hydride gas reacts with the Group-III metal which then reacts with a nitrogen precursor to form the Group-III metal nitride.

As the demand for LEDs, LDs, transistors, and integrated circuits increases, the efficiency of depositing the Group-III metal nitride takes on greater importance. Therefore, there is a need in the art for an improved HVPE deposition method and an HVPE apparatus.

### SUMMARY OF THE INVENTION

The present invention generally comprises a HVPE deposition method and apparatus. In one embodiment, a hydride vapor phase epitaxial method is disclosed. The method comprises positioning at least one substrate in a chamber, flowing a metal chloride gas and a first nitrogen precursor across the chamber, directing the first nitrogen precursor and the metal chloride to flow substantially tangential to the deposition surface of the substrate by flowing a purge gas into the chamber in a direction substantially perpendicular to the deposition surface, and reacting the first nitrogen precursor with the metal chloride to deposit a metal nitride on the at least one substrate.

In another embodiment, a hydride vapor phase epitaxial apparatus is disclosed. The apparatus comprises a chamber having a chamber body, a substrate carrier having a surface for receiving one or more substrates disposed within the chamber body, a source boat disposed within the chamber body and adjacent the substrate carrier, a first gas inlet coupled to a nitrogen precursor source and the chamber body, a second gas inlet separate from the first gas inlet and coupled with a hydride gas source and the chamber body, and one or more third gas inlets coupled with the chamber body and oriented to direct gas into the chamber body in a direction substantially perpendicular to the surface for receiving the one or more substrates.

In yet another embodiment, a hydride vapor phase epitaxial apparatus is disclosed. The apparatus comprises a substrate carrier disposed within a chamber body, a source boat disposed within the chamber body and adjacent the substrate carrier, and a cover coupled with the boat. The boat has a gas passage bounded by a wall having a plurality of openings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of an HVPE chamber according to one embodiment of the invention.

FIG. 2A is a schematic perspective view of the HVPE chamber of FIG. 1.

FIG. 2B is a schematic perspective view of the source boat of FIG. 2A.

FIG. 3 is a schematic top view of the HVPE chamber of FIG. 1.

FIG. 4 is another schematic cross sectional view of the HVPE chamber of FIG. 1.

FIG. 5 is a schematic cross sectional view of an HVPE chamber according to another embodiment of the invention.

FIG. 6 is a schematic cross sectional view of an HVPE chamber according to another embodiment of the invention.

FIG. 7A is a schematic cross sectional view of the gas manifold according to one embodiment of the invention.

FIG. 7B is a schematic view of the gas manifold of FIG. 7A.

FIG. 8A is a schematic cross sectional view of the gas manifold according to another embodiment of the invention.

FIG. 8B is a schematic view of the gas manifold of FIG. 8A.

FIG. 9 is a schematic cross sectional view of an HVPE chamber according to another embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

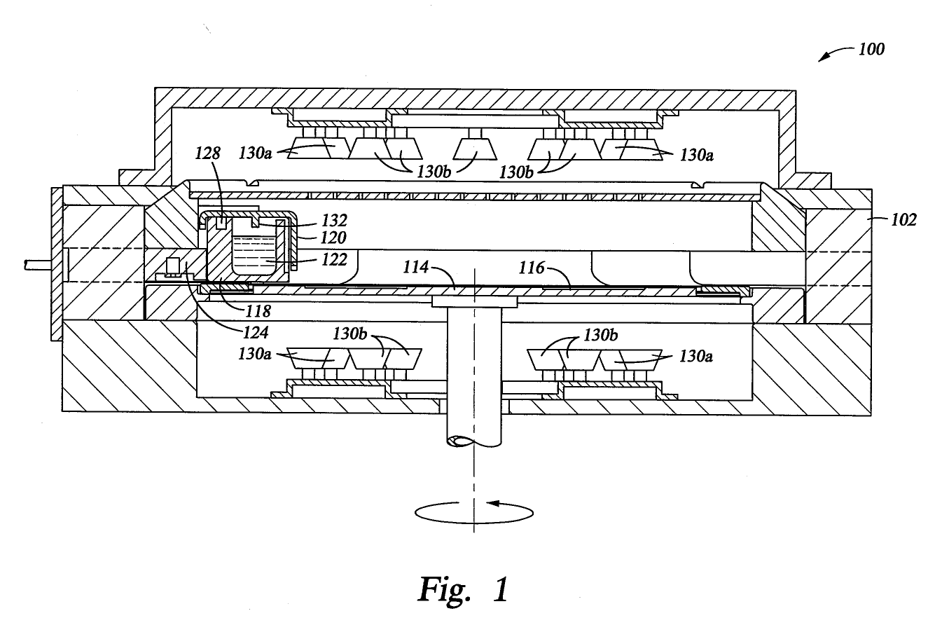

The present invention generally comprises a HVPE deposition method and apparatus. FIG. 1 is a schematic cross sectional view of an HVPE chamber that may be used to practice the invention according to one embodiment of the invention. Exemplary chambers that may be adapted to practice the present invention are described in U.S. patent application Ser. Nos. 11/411,672 and 11/404,516, both of which are incorporated by reference in their entireties. Another design that may be adapted to practice the present invention includes an EPI RP 200 mm chamber, available from Applied Materials, Santa Clara, Calif.

The apparatus 100 in FIG. 1 comprises a chamber body 102 that encloses a processing area. A substrate carrier 114 is disposed within the chamber body 102. The substrate carrier 114 may comprise one or more recesses 116 within which one or more substrates may be disposed during processing. The substrate carrier 114 may carry six or more substrates. In one embodiment, the substrate carrier 114 carries eight substrates. It is to be understood that more or less substrates may be carried on the substrate carrier 114. In certain embodiments, the substrates may comprise sapphire. In other embodiments, the substrates may comprise SiC, silicon, or GaN. It is to be understood that other types of substrates, including glass substrates, may be processed. In one embodiment, the substrate carrier 114 may be about 200 mm in diameter. In another embodiment, the substrate carrier 114 may be about 300 mm in diameter. In one embodiment, the substrates may be about one inch to about 4 inches in diameter. In another embodiment, the substrates may be about 2 inches in diameter. It is to be understood that substrates of other sizes may be processed within the apparatus 100 and according to the processes described herein. The substrate carrier 114 may rotate about its central axis during processing. In one embodiment, the substrates may be individually rotated within the substrate carrier 114. The substrate carrier 114 may comprise silicon carbide.

A plurality of lamps 130a, 130b may be disposed both above and below the substrate carrier 114. In certain embodiments, the lamps may be arranged in concentric circles. For example, the inner array of lamps 130b may comprise eight lamps, and the outer array of lamps 130a may comprise twelve lamps. It is understood that other arrangements and other numbers of lamps are possible. The arrays of lamps 130a, 130b may be selectively powered to heat the inner and outer areas of the substrate carrier 114. In one embodiment, the lamps 130a, 130b are collectively powered as inner and outer arrays in which the top and bottom arrays are either collectively powered or separately powered. In another embodiment, the lamps 130a, 130b are each individually powered. In yet another embodiment, separate lamps or heating elements may be positioned over and/or under the source boat 118. It is to be understood that the invention is not restricted to the use of arrays of lamps. Any suitable heating source may be utilized to ensure that the proper temperature is adequately applied to the processing chamber, substrates therein, and metal source 122. For example, it is contemplated that a rapid thermal processing lamp system may be utilized such as is described in United States Patent Publication No. 2006/0018639 A1, which is incorporated by reference in its entirety.

The metal source 122 may be disposed within a source boat 118 adjacent to the processing area within the chamber body 102. The source boat 118 is disposed within the processing area above the substrate carrier 114. The source boat 118 is disposed outside of the recess 116 where the substrates rest. The source boat 118 may be formed of quartz. The source boat 118 may be enclosed by a cover 120. The cover 120 may comprise a baffle 132 that extends into a cavity of the source boat 118. In yet another embodiment, multiple baffles 132 may extend from the cover 120. The baffles 132 may be of different shape or extend different distances from the cover 120. The baffles 120 may be arranged to create a labyrinth through which gas may pass. A gas passage 128 may be present adjacent the metal source 122 within the source boat 118 to permit passage of a gas. A gas manifold 124 may be disposed adjacent the source boat 118.

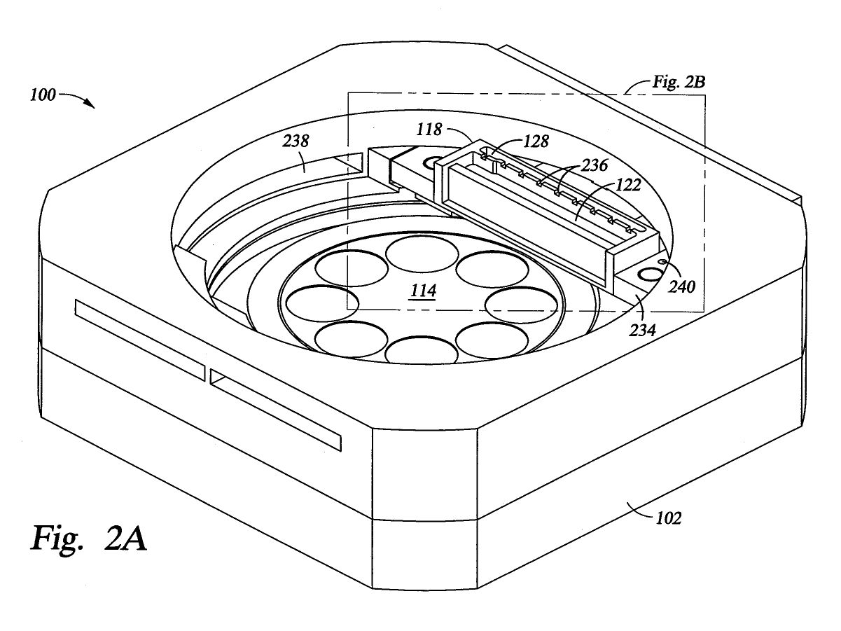

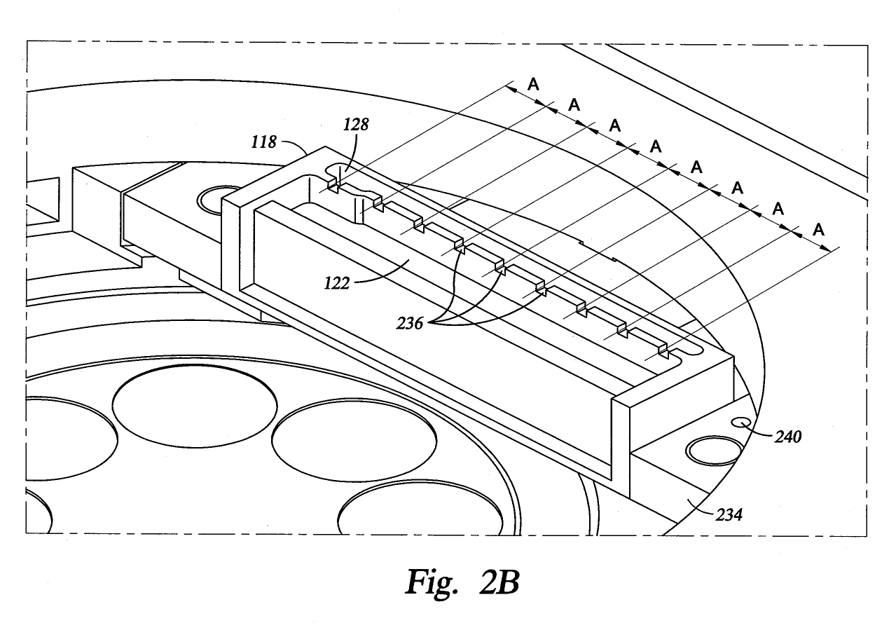

FIG. 2A is a schematic perspective view of the HVPE chamber of FIG. 1. The substrate carrier 114 may be positioned within the apparatus 100 on a susceptor (not shown) through a slot 238 present in the chamber body 102 by a positioning robot (not shown). The substrates may be disposed on the substrate carrier 114 adjacent the source boat 118. As shown in FIG. 2B, the source boat 118 may have a plurality of openings 236 in the wall bounding the gas passage 128. The openings 236 may be evenly spaced along the gas passage 128 as shown by the arrows “A” to permit an even flow of gas through the source boat 118. The source boat 118 may be disposed adjacent a gas manifold 234 having a passage 240 through which purge gas may be provided. In one embodiment, the plurality of openings 236 may be disposed below the surface of the metal source 122 so that the gas bubbles up through the metal source 122.

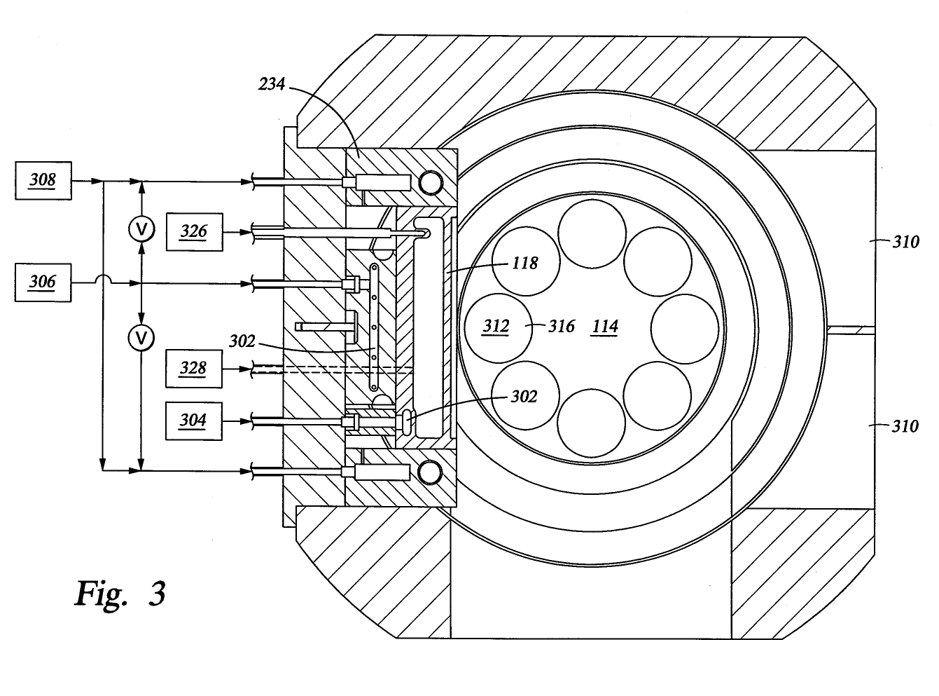

FIG. 3 is a schematic top view of the HVPE chamber of FIG. 1. Hydride gas may be provided to the source boat 118 from a chlorine containing gas source 304 through a gas inlet 302 into the passage 128 (shown in FIG. 1). A nitrogen precursor may be provided to the source boat 118 through a gas inlet 302 into the gas manifold 124 from a gas source 306. Purge gas may be provided to the gas manifold 234 from a purge gas source 308. The temperature of the metal source 122 may be monitored by a thermocouple 326. In one embodiment, the gas source 306 may be coupled with the gas manifold 234 disposed adjacent the source boat 118. In one embodiment, the nitrogen precursor may instead be hydrogen gas or a mixture of hydrogen gas and nitrogen precursor. In one embodiment, the purge gases may comprise nitrogen, hydrogen, and mixtures thereof. Additionally, argon may be provided with the hydrogen and/or nitrogen for both the purge gas and the gas from source 306.

Diametrically opposite the source boat 118, a chamber exhaust 310 may be present. By placing the chamber exhaust 310 diametrically opposite the source boat 118, gases introduced in an area near the source boat 118 will flow across the deposition surface 312 of the substrates 31.6 disposed on the substrate carrier 114.

As may be seen in FIG. 3, the source boat 118 does not extend over the substrates 316 on the substrate carrier 114. By disposing the source boat 118 adjacent the substrate carrier 114, the source boat 118 does not interfere with substrate 316 insertion or removal. Additionally, the source boat 118 does not interfere with gas flow across and/or perpendicular to the substrates 316.

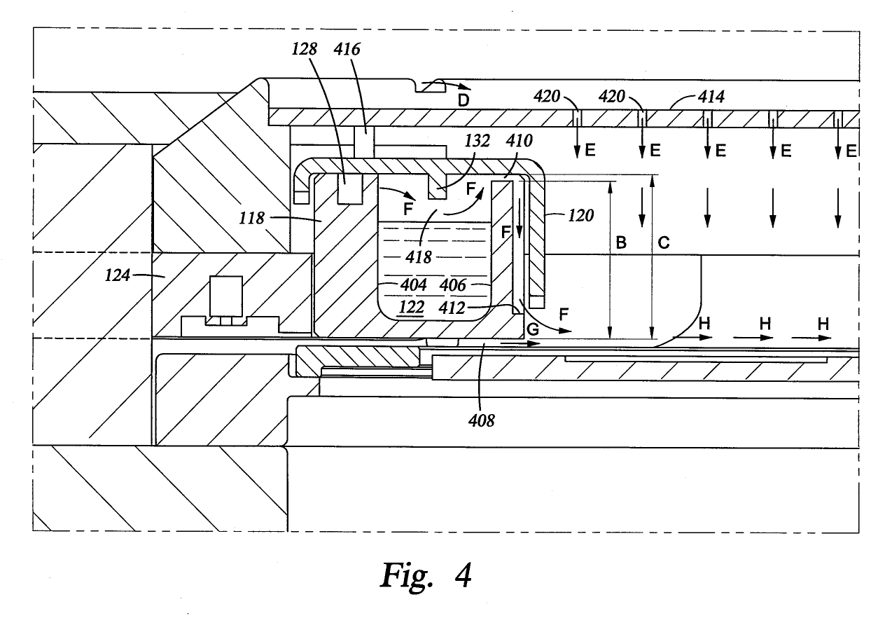

FIG. 4 is another schematic cross sectional view of the HVPE chamber of FIG. 1. The source boat 118 may comprise a cavity 418 within which the metal source 122 may be disposed. The cavity 418 may be bound by a plurality of walls 404, 406. One of the walls 406 may have a height “B” which is shorter than the height “C” of another wall 404. The shorter wall 406 may be disposed on the side of the source boat 118 adjacent to the substrate carrier 114. The shorter wall 406 permits a space 410 to be present between the cover 120 and the source boat 118. The space 410 permits passage of gas out of the source boat 118 and over a lip 412 to the substrate carrier 114.

Inert gas fed into the manifold 234 may flow through a conduit 416 to the top plate 416 where the inert gas may flow out of a plurality of openings 420. The nitrogen precursor may be fed through the gas manifold 124 and into the chamber body 102 through a gas inlet 408.

The process may be used to deposit various metal nitride layers including GaN, AlN, InN, AlGaN, and InGaN. During processing, the substrates are initially positioned in the chamber body 102 through the slot 238 (see FIG. 2A). The chamber may be maintained at a chamber pressure of about 760 Torr down to about 100 Torr. In one embodiment, the chamber is maintained at a pressure of about 450 Torr to about 760 Torr. The metal source 122 is positioned within the source boat 118 while chlorine containing gas, purge gas, and nitrogen precursor are provided to the chamber.

The metal source 122 may be previously disposed within the source boat 118 or supplied on an “as needed” basis to the source boat 118 from a metal supply 328. In one embodiment, the metal source 122 may comprise gallium, aluminum, indium, and combinations thereof. The substrate carrier 112 may be rotated. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform exposure of the processing gases to each substrate 316.

In the embodiment where the metal source is not provided from the metal supply 326 disposed outside the chamber, it is preferable that the amount of metal source 122 within the cavity 418 of the source boat 118 be sufficient to ensure a significant amount of substrates may be processed before the apparatus 100 would need to be opened to replenish the metal source 122. Whenever the apparatus is opened to ambient air, it may take about 1 day to about 2 days of downtime before the apparatus is ready to process substrates again due to pumping times, chamber cleaning, and metal source purifying. Whenever the metal source 122 is exposed to atmospheric air, it may prematurely react with the oxygen in the air to form a metal oxide such as GaO on the surface of the liquid metal. The metal oxide forms a “skin” over the liquid metal that prevents the liquid metal from reacting with the nitrogen precursor to form the metal chloride. Thus, all traces of oxygen need to be removed before the further processing. The downtime between processing may be significant if sufficient metal source 122 is not initially provided to the source boat 118. Therefore, the size and shape of the source boat 118 as well as the amount of metal source 122 positioned within the cavity 418 of the source boat 118 should be predetermined to ensure an optimal level of substrate throughput.

One or more lamps 103a, 130b may be powered to heat the substrates as well as the source boat 118. The lamps may heat the substrate to about 1,000 degrees Celsius to about 1,100 degrees Celsius. In another embodiment, the lamps 130a, 130b maintain the metal source 122 within the source boat 118 at a temperature of about 700 degrees Celsius to about 900 degrees Celsius. A thermocouple 326 may be positioned to measure the metal source 122 temperature during processing. The temperature measured by the thermocouple may be fed back to a controller that adjusts the heat provided from the heating lamps 130a, 130b so that the temperature of the metal source 122 may be controlled or adjusted as necessary.

A hydride gas may be provided from a hydride gas source 304 to the gas inlet 302 in the source boat 118. The hydride gas may include a precursor gas such as HX where X may include chlorine, bromine, or iodine. The hydride gas flows through the gas passage 128 and through the openings 236 in the wall 404 of the source boat 118. The even spacing of the openings 236 in the wall 404 permits the chlorine containing gas to flow evenly into the cavity 418 of the source boat 118. When the gas comprises chlorine, the hydride gas reacts with the metal source to form a metal chloride and hydrogen gas. In one embodiment, the hydride gas comprises HCl.

The HCl flows into the cavity 418 where a baffle 132 alters the flow path of the HCl (shown by arrows “F”) through the source boat 118. By altering the flow path of the HCl through the cavity 418, the residence time that the metal source 122 is exposed to the HCl may be increased. By increasing the residence time, the amount of metal and HCl converted to metal chloride and hydrogen is increased.

In one embodiment, the HCl is provided to the source boat 118 at a rate of about 50 sccm to about 2 slm. In another embodiment, the HCl may be provided with a carrier gas. The carrier gas may comprise nitrogen gas or hydrogen gas or an inert gas. The carrier gas may be provided at a flow rate of about 0 slm to about 1 slm. The flow rate of the HCl and the carrier gas together may be about 500 sccm to about 1 slm.

In another embodiment, the cover 120 may have one or more holes therein. The HCl would then be fed, either additionally or alternatively, through the holes within the cover 120 to the cavity 418 where it may then react with the metal source 122. The holes may be designed to control the direction of the flow of the HCl into the cavity 418 so that the residence time of the HCl within the cavity 418 may be maximized.

Once the metal source 122 and the HCl react to form the metal chloride and hydrogen gas, the gases then flow over the short wall 406 of the source boat 118 through the opening 410 between the short wall 406 and the cover 120. The gases then travel down between the short wall 406 and the cover 120 to a lip 412 of the source boat 118. The lip 412 alters the flow path of the gases so that the gases exit the source boat 118 and cover 120 to flow substantially tangential to the deposition surface of the substrates.

A nitrogen precursor may be provided from gas source 306 to the chamber body 102 through the gas manifold 124. In one embodiment, the nitrogen precursor may comprise ammonia. The ammonia may exit the gas manifold 124 through an opening 408 disposed under the source boat 118 and flow in a direction substantially tangential to the substrates as shown by arrow “G”. By flowing the ammonia under the source boat 118, the ammonia and the metal chloride may not contact each other and prematurely react to deposit on undesired surfaces. If the ammonia is co-flowed with the HCl through the source boat 118, the metal chloride and the ammonia may react within the source boat and thus deposit on an undesired surface. In one embodiment, the ammonia is provided to the processing area at a rate of about 1 slm to about 15 slm. In another embodiment, the ammonia may be co-flowed with a carrier gas such as those described above.

Purge gas may be provided to the chamber body 102 from the purge gas source 308. In one embodiment, the purge gas may be an inert gas such as argon or helium. In another embodiment the purge gas may comprise hydrogen gas or nitrogen gas. The purge gas travels from the purge gas source 308 to the gas manifold 234 and then through the conduit 416 to the top plate 414 where the purge gas exhausts through openings 420 that are disposed to provide the purge gas to the chamber body in a direction perpendicular to the axis of rotation of the substrates as shown by arrows “E”. The purge gas also flow out the top of the top plate 414 as shown by arrows “D”. The purge gas prevents the metal nitride from depositing on upper portions of the chamber.

The openings 420 permit the purge gas to flow perpendicular to the axis of rotation the substrates. The openings 420 enable the metal chloride gas and the nitrogen containing gas to flow across the chamber. The purge gas pushes the metal chloride gas and the nitrogen precursor downward towards the substrates so that the nitrogen precursor and the metal chloride gas flow substantially tangential to the deposition surface of the substrates as shown by the arrows “H”. The chamber exhaust channels 310 additionally pull the metal chloride gas and the nitrogen precursor across the deposition surfaces. Thus, the combination of the direction of the purge gas flow and the exhaust help flow the nitrogen precursor and the metal chloride gas tangential to the deposition surface of the substrates. In one embodiment, the nitrogen precursor may be co-flowed with the purge gas through the top plate 414 and out the openings 420 so that the purge gas and the nitrogen precursor flow into the processing area in a direction substantially perpendicular to the axis of rotation for the substrates.

As all of the gases are provided to the chamber, the purge gases push the nitrogen precursor and metal chloride gases down towards the rotating substrates. The flow of the metal chloride and the nitrogen precursor is substantially tangential to the deposition surface of the substrates due to the direction of flow of the purge gas and the pull of the gases by the chamber exhaust. As the nitrogen precursor and the metal chloride travel across the chamber and react, a metal nitride may be deposited onto the substrates. The metal nitride may deposit on the substrates at a rate of about 5 microns per hour to about 25 microns per hour. In one embodiment, the deposition rate is about 15 microns per hour to about 25 microns per hour.

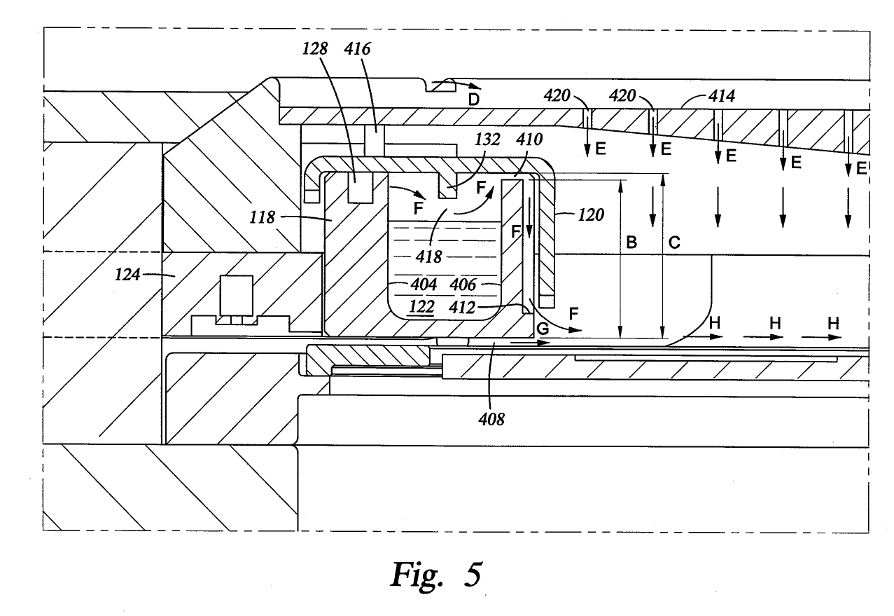

In one embodiment, the top plate 414 may be sloped. As may be seen in FIG. 5, the sloped top plate 414 introduces the purge gas to flow through the openings 420 and enter the processing space closer to the substrates. Additionally, by sloping the top plate 414, the metal chloride and the nitrogen precursor may be further confined to the area above the substrates.

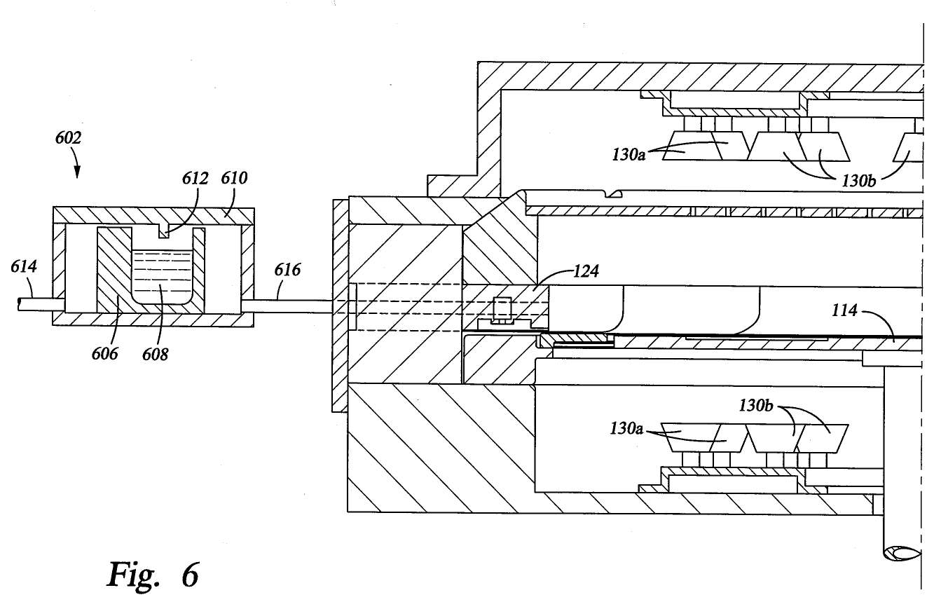

In another embodiment, the metal source may be moved outside the processing chamber. FIG. 6 shows an embodiment where the metal source 602 is disposed outside the processing chamber. One advantage of disposing the metal source outside the chamber is that the metal source may be replenished without the need to open the chamber. By not opening the chamber, process downtime may be reduced. When the metal source 602 is disposed outside the processing chamber, the metal source 602 may comprise a container 604 housing a boat 606 within which the metal 608 will be disposed. A lid 610 of the container 604 may comprise one or more baffles 612 as discussed above in other embodiments. The hydride vapor may be fed to the container through a conduit 614 and the metal chloride may exit the metal source 602 through a conduit 616 to enter the processing chamber.

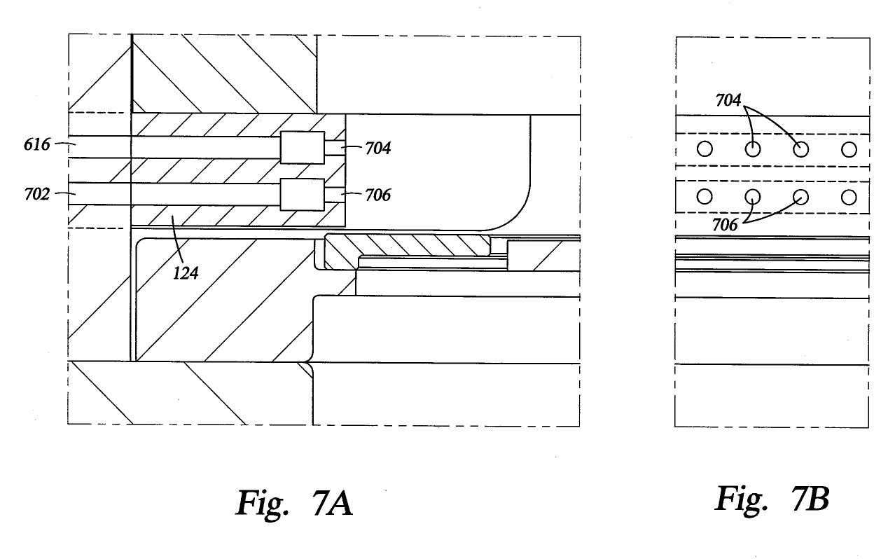

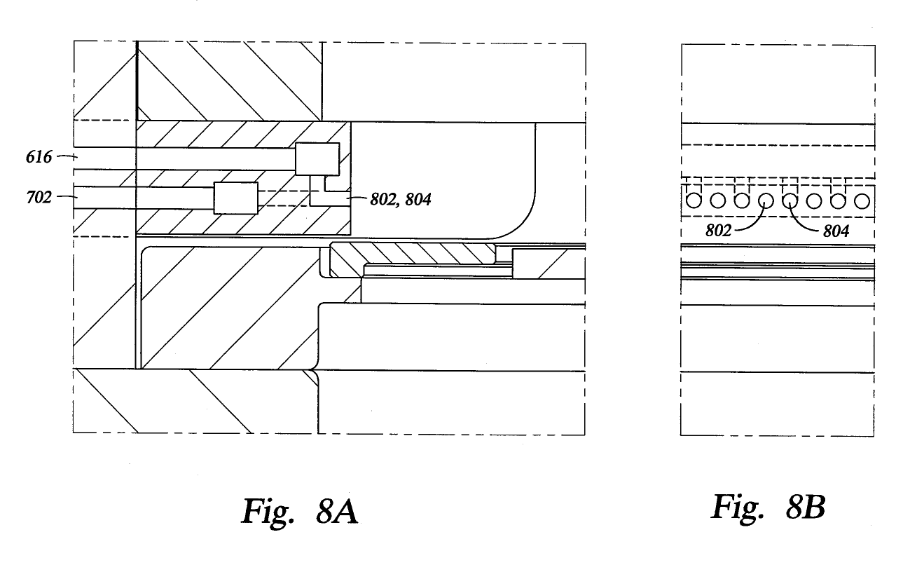

When the metal source is disposed outside the chamber, the metal chloride may pass through the same gas manifold 124 as the nitrogen precursor. As shown in FIG. 7A, the nitrogen precursor may enter the manifold through a conduit 702 and exit the manifold into the processing chamber through a gas inlet 706. The metal chloride may exit the gas manifold 124 and into the processing chamber through a gas inlet 704. As may be seen in FIG. 7B, the gas inlets 704 for the metal chloride gas may be disposed above the gas inlets 706 for the nitrogen precursor. It should be understood that the gas inlets could be reversed so that the gas inlets 706 for the nitrogen precursor are disposed above the gas inlets 704 for the metal chloride. Alternatively, gas inlets 802 for the nitrogen precursor and the metal chloride 804 may be disposed side by side as shown in FIGS. 8A and 8B. It should be understood that the gas inlets 802, 804 may be disposed in one or more rows across the face of the gas manifold 124. To ensure the metal chloride and the nitrogen precursor effectively react and deposit onto the substrates, the gas inlets 704, 706, 802, 804 may be disposed about one inch away from the substrate carrier. In another embodiment, the gas inlets 704, 706, 802, 804 may be disposed about one inch away from the substrates.

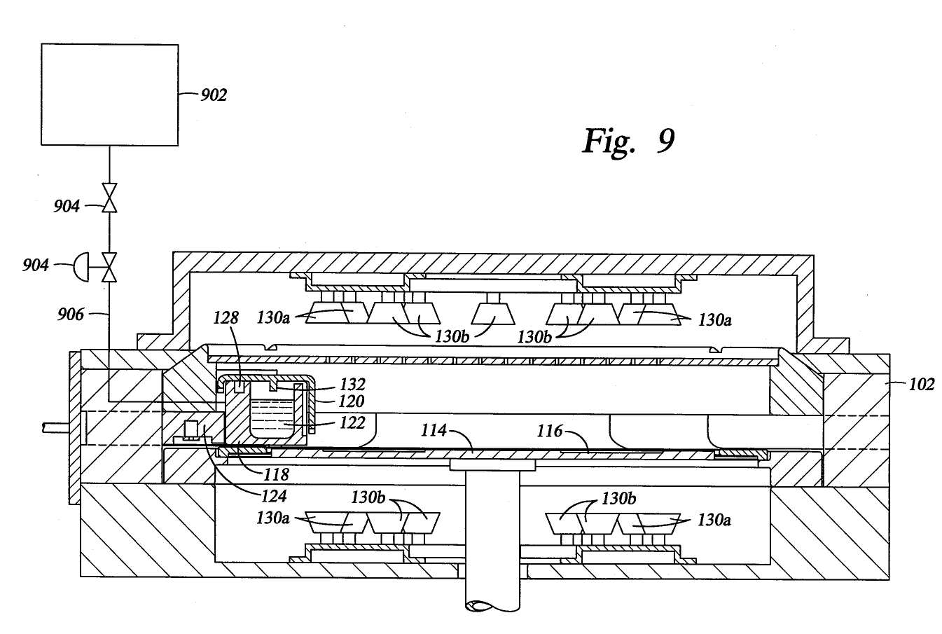

In another embodiment of the invention, the boat 118 may be fed with metal source from an outside source 902 on an as needed basis. FIG. 9 shows a supplemental source 902 disposed outside the chamber. Whenever the metal source 122 needs to be replenished, additional metal may be provided to the boat 118 from the supplemental source 902. The supplemental source 902 may be provided with its own heating system to ensure the metal is maintained at the desired temperature. The supplemental source 902 may be gravity fed to the boat 118 by opening one or more valves 904 along a conduit 906 to the boat 118 to allow the affects of gravity to permit the metal to flow to the boat 118 inside the processing chamber. In one embodiment, the metal source may be injected into the boat 118 from a supplemental source 902.

A source boat disposed within a processing chamber capable of processing multiple substrates simultaneously may be beneficial in increasing substrate throughput. Directing the metal chloride and nitrogen containing gases to flow substantially tangential to the deposition surface of the substrate increases efficiency of HVPE deposition so that multiple substrates may be processed simultaneously.

While the foregoing is directed to embodiments of the present invention, other and further embodiments of the invention may be devised without departing from the basic scope thereof, and the scope thereof is determined by the claims that follow.

1. A method of forming a metal nitride, comprising:
providing a substrate carrier adapated to hold at least one substrate;
introducing a metal chloride gas and a first nitrogen precursor at one end of the substrate carrier;
providing a purge gas flowing downward toward the substrate carrier so that the metal chloride gas and the first nitrogen precursor flows toward the substrate carrier; and
exhausting the metal chloride gas, the first nitrogen precursor, and the purge gas at the opposite end of the substrate carrier in which the metal chloride gas and the first nitrogen precursor were introduced.

2. The method of claim 1, further comprising:
flowing a chlorine containing gas through a boat disposed within the chamber, the boat containing at least one metal selected from the group consisting of gallium, aluminum and indium therein to form the metal chloride gas; and
flowing the first nitrogen precursor into the chamber under the boat.

3. The method of claim 2, wherein the chlorine containing gas flows through a plurality of evenly spaced openings in the boat and over the at least one metal.

4. The method of claim 3, further comprising:
diverting the flow of the chlorine containing gas such that the chlorine containing gas travels in a non-linear path over the at least one metal.

5. The method of claim 1, wherein the first nitrogen precursor comprises NH₃ and the chlorine containing gas comprises HCl.

6. The method of claim 1, further comprising:
rotating the at least one substrate.

7. The method of claim 1, further comprising:
flowing a second nitrogen precursor with the purge gas, the second nitrogen precursor flowed separate from the first nitrogen precursor.

8. The method of claim 1, further comprising:
directing the first nitrogen precursor and the metal chloride gas to flow substantially tangential to a deposition surface of the substrate by flowing the purge gas in a direction substantially perpendicular to the deposition surface; and
reacting the first nitrogen precursor with the metal chloride to deposit the metal nitride on the at least one substrate.

9. A hydride vapor phase epitaxial apparatus, comprising:
a chamber having a chamber body;
a substrate carrier disposed within the chamber body, the substrate carrier having a surface for receiving one or more substrates;
a source boat disposed within the chamber body and adjacent the substrate carrier;
a first gas inlet coupled to a nitrogen precursor source and the chamber body;
a second gas inlet separate from the first gas inlet, the second gas inlet coupled with a hydride source and the chamber body; and
one or more third gas inlets coupled with the chamber body and oriented to direct gas into the chamber body in a direction substantially perpendicular to the surface for receiving the one or more substrates.

10. The apparatus of claim 9, wherein the source boat further comprises:
a channel coupled with the second gas inlet;
a source cavity adjacent the channel; and
a plurality of openings coupling the channel to the source cavity, wherein the openings are substantially evenly spaced apart.

11. The apparatus of claim 10, further comprising:
a cover coupled with the source boat, the cover having at least one baffle extending into the source cavity, wherein the first gas inlet is positioned between the source boat and the substrate carrier, and wherein the second gas inlet is positioned within the source boat.

12. The apparatus of claim 10, wherein the source cavity is bound by a plurality of walls and wherein one of the walls has a different height compared to a remainder of the walls.

13. The apparatus of claim 9, wherein the one or more third gas inlets are coupled with the nitrogen precursor source.

14. The apparatus of claim 9, further comprising:
one or more first heat sources disposed above the substrate carrier; and
one or more second heat sources disposed below the substrate carrier.

15. The apparatus of claim 9, wherein the substrate carrier is rotatable.

16. A hydride vapor phase epitaxial apparatus, comprising:
a rotatable substrate carrier disposed within a chamber body, the substrate carrier capable of holding a plurality of substrates;
a source boat disposed within the chamber body and adjacent the substrate carrier, the boat having a gas passage bounded by a wall having a plurality of openings; and
a cover coupled with the boat.

17. The apparatus of claim 16, wherein the cover further comprises at least one baffle extending into the source boat.

18. The apparatus of claim 16, further comprising:
one or more first heat sources disposed above the substrate carrier; and
one or more second heat sources disposed below the substrate carrier.

19. The apparatus of claim 16, further comprising:
a gas inlet disposed between the source boat and the substrate carrier.

20. The apparatus of claim 16, further comprising:
a chamber exhaust diametrically disposed across the chamber body from the source boat.

21. A hydride vapor phase epitaxial apparatus, comprising:
a rotatable substrate carrier disposed within a chamber body, the substrate carrier capable of holding a plurality of substrates;
a gas manifold disposed within the chamber body; and
a first source boat disposed outside the chamber body and coupled with the chamber body.

22. The apparatus of claim 21, wherein the first source boat is coupled with the gas manifold.

23. The apparatus of claim 22, wherein the gas manifold further comprises:
a plurality of inlets, wherein at least one of the plurality of inlets is coupled with the first source boat and at least one other inlet of the plurality of inlets is coupled with a nitrogen precursor source.

24. The apparatus of claim 21, further comprising:
a second source boat disposed within the chamber body coupled with the first source boat.
